(19) United States
(12) Patent Application Publication
(10) Pub. No.: US 2007/0158852 A1
(43) Pub. Date: Jul. 12, 2007

(54) Circuit Board with Conductive Structure and Method for Fabricating the same

(75) Inventor: Shih-Ping Hsu, Hsin-chu (TW)

Correspondence Address: FULBRIGHT AND JAWORSKI LLP, 555 S. FLOWER STREET, 41ST FLOOR, LOS ANGELES, CA, 90071, US

(73) Assignee: PHOENIX PRECISION TECHNOLOGY CORPORATION, Hsin-chu (TW)

(21) Appl. No.: 11/467,296

(22) Filed: Aug. 25, 2006

(30) Foreign Application Priority Data
Jan. 9, 2006 (TW) 095100716

(51) Int. Cl. H01L 23/48; H01L 21/44

(52) U.S. Cl. 257/774; 438/652; 438/675; 438/678; 257/781

(57) ABSTRACT

A method for fabricating a circuit board with a conductive structure and the same are proposed. A buffer metal layer is formed on an electrically connecting pad of a circuit layer of a circuit board in advance. A conductive structure is then formed on the buffer metal layer to form the conductive structure of the present invention and is connected to the circuits located in the different layers of the circuit board. The combining strength of the conductive structure and the electrically connecting pad is reinforced by the buffer metal layer as the buffer metal layer has high ductility. The long-term electrical quality and stability are also enhanced.

### FIELD OF THE INVENTION

The present invention relates to circuit boards with conductive structures and a method for fabricating the same, and more particularly, to a circuit board with a conductive blind via and a method for fabricating the same.

### BACKGROUND OF THE INVENTION

Circuit designs for circuit boards and packaging substrates tend to become denser in order to meet the demands for miniaturization and increased functionalities of electronic products. Accordingly, multi-layer circuit board with thin circuits and high density is the trend for the next generation. Conductive structures for electrically connecting circuit layers in a multi-layer circuit board are one of the main factors that affect the quality for electrically connection of the circuit board.

Traditionally, conductive blind vias are employed for connection between the circuit layers of a circuit board, as shown in FIGS. 1A to 1C. First referring to FIG. 1A, a dielectric layer 12 is formed on a circuit board 1 with a circuit layer 11. The circuit layer 11 has at least an electrically connecting pad 110. A via 120 is formed in the dielectric layer 12 corresponding to the electrically connecting pad 110 for exposing the electrically connecting pad 110. The electrically connecting pad 110 may electrically conduct with an inner circuit layer (not shown) of the circuit board 1 by a conductive structure (not shown).

Referring to FIG. 1B, a conductive layer 13 is formed on the surface of the dielectric layer 12 and in the via 120 so as to allow electrical connection between the conductive layer 13 and the electrically connecting pad 110.

Referring to FIG. 1C, a metal layer is further electroplated on the conductive layer 13 so a conductive blind via 141 is formed in the via 120 of the dielectric layer 12 and another circuit layer 14 is formed as a result of patterning of the metal layer. The circuit layer 14 is electrically connected to the circuit layer 11 of the circuit board 1 by the conductive blind via 141.

However, in the case of the aperture of the above-described via 120 is reduced to be smaller than 60 μm and the thickness of the dielectric layer 12 and the via 120 is relatively larger, layering or fractures may be produced at the bottom of the via 120 due to large inner stress during a subsequent lead-free process for forming of the conductive blind via 141 in the via 120 of the dielectric layer 12 and/or a reliability test of the circuit board. This may cause open circuit or micro open circuit and severely degrades the quality and stability of electrically connection of the circuit board.

Moreover, in order to reinforce the combining strength between the conductive via and the electrically connecting pad, a micro-roughing method is typically adopted in the prior art that roughens the circuit layers using the micro-etching technique. During micro-etching, since the width of the circuit line is usually smaller that that of the electrically connecting pad and the speed of chemical etching cannot be easily controlled, the circuit line may already be etched away when the electrically connecting pad reaches a proper roughness. Conversely, if the chemical etching time is reduced to avoid overly etching the circuit line, the surface of the electrically connecting pad may not be rough enough, reducing the combining strength between the conductive blind via and the electrically connecting pad. Accordingly, aforementioned problems of open circuit or micro open circuit may easily occur.

Therefore, there is a need for a solution that enhances the combining strength between the conductive blind via and the electrically connecting pad so as to increase the electrical quality and stability of a circuit board.

### SUMMARY OF THE INVENTION

In the light of forgoing drawbacks, an objective of the present invention is to provide a circuit board with a conductive structure and its fabricating method that avoids layering or fractures at the bottom of the conductive structure so as to enhance the quality and reliability of electrically connection of the circuit board.

Another objective of the present invention is to provide a circuit board with a conductive structure and its fabricating method that reinforces the combing strength between an electrically connecting pad on a circuit layer with the conductive structure on another circuit layer.

Still another objective of the present invention is to provide a circuit board with a conductive structure and its fabricating method that enhances the electroplating quality and reliability of the conductive structure.

In accordance with the above and other objectives, the present invention provides a method for fabricating a circuit board with a conductive structure, comprising providing a circuit board with a circuit layer having at least an electrically connecting pad; forming a dielectric layer on the circuit board and the circuit layer and at least a via formed in the dielectric layer for exposing the electrically connecting pad; forming a buffer metal layer on the electrically connecting pad in the via of the dielectric layer; and forming a conductive structure on the buffer metal layer in the via.

In the above method for fabricating a circuit board with a conductive structure, a conductive layer may be further formed between the conductive structure and the buffer metal layer. A conductive structure may be formed using the conductive layer. In addition, during the process of forming the conductive structure, another circuit layer may be formed on the surface of the dielectric layer. The another circuit layer can be electrically connected to the circuit layer of the circuit board through the conductive structure and the buffer metal layer.

The above buffer metal layer can be made of a material with high ductility using an electroplating or electroless plating process. The material may for example be one selected from the group consisting of gold, silver, titanium, beryllium and alloys thereof. Preferably, the buffer metal layer is formed as a gold layer using an electroless plating process. The conductive structure may be made of copper, gold, silver, nickel or aluminum.

The present invention further discloses a circuit board with a conductive structure, comprising: a circuit layer having at least an electrically connecting pad formed on the circuit board; a dielectric layer formed on the circuit board with the circuit layer and at least a via formed in the dielectric layer for exposing the electrically connecting pad; a buffer metal layer formed on the electrically connecting pad in the via of the dielectric layer; and a conductive structure formed on the buffer metal layer.

A conductive layer may be further formed between the above conductive structure and the buffer metal layer. In addition, during the process of forming the conductive structure, another circuit layer may be formed on the surface of the dielectric layer.

The above buffer metal layer can be made of a material with high ductility using an electroplating or electroless plating process. The material may for example be one selected from the group consisting of gold, silver, titanium, beryllium and alloys thereof. Preferably, the buffer metal layer is formed as a gold layer using an electroless plating process. The conductive structure may be made of copper, gold, silver, nickel or aluminum.

Compared to the prior art, the present invention forms a buffer metal layer on the electrically connecting pad of the first circuit layer. Since the material of the buffer metal layer is characterized by high combining strength and high ductility, it can be easily combined with the electrically connecting pad or the subsequently formed conductive structure. Thus, the combining strength of the conductive structure and the electrically connecting pad is reinforced by the buffer metal layer. In addition, layering or fractures at the bottom of the conductive structure causing open circuit or micro open circuit can be avoided, therefore enhancing the electrical quality and stability of the circuit board.

Moreover, since the buffer metal layer covers and protects the electrically connecting pad underneath, the electrically connecting pad is avoided from over etching during a micro-etching process, thus enhancing the electroplating quality and reliability of the subsequently formed conductive structure.

### BRIEF DESCRIPTION OF THE DRAWINGS

The present invention can be more fully understood by reading the following detailed description of the preferred embodiments, with reference made to the accompanying drawings, wherein:

FIGS. 1A to 1C (PRIOR ART) are cross-sectional views depicting a traditional circuit board with a conductive structure;

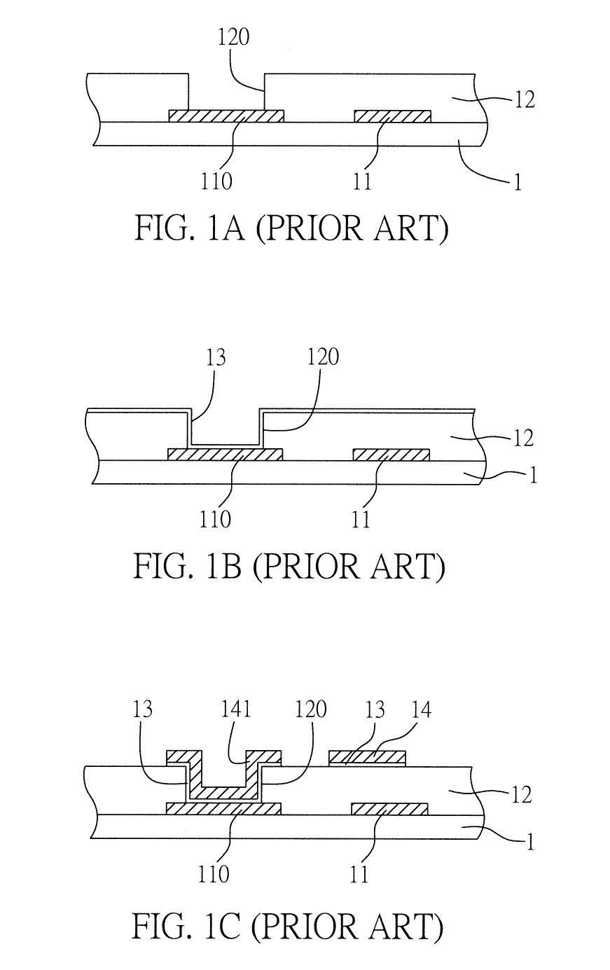

FIGS. 2A to 2D are cross-sectional views illustrating a circuit board with a conductive structure and its fabricating method of the present invention;

FIG. 2D′ is a cross-sectional view depicting another embodiment of FIG. 2D;

FIGS. 3A to 3C are cross-sectional views illustrating a circuit board with a conductive structure and its fabricating method of the present invention; and

FIG. 3C′ is a cross-sectional view depicting another embodiment of FIG. 3D.

### DETAILED DESCRIPTION OF THE EMBODIMENTS

The present invention is described by the following specific embodiments. Those with ordinary skills in the arts can readily understand the other advantages and functions of the present invention after reading the disclosure of this specification. The present invention can also be implemented with different embodiments. Various details described in this specification can be modified based on different viewpoints and applications without departing from the scope of the present invention.

### First Embodiment

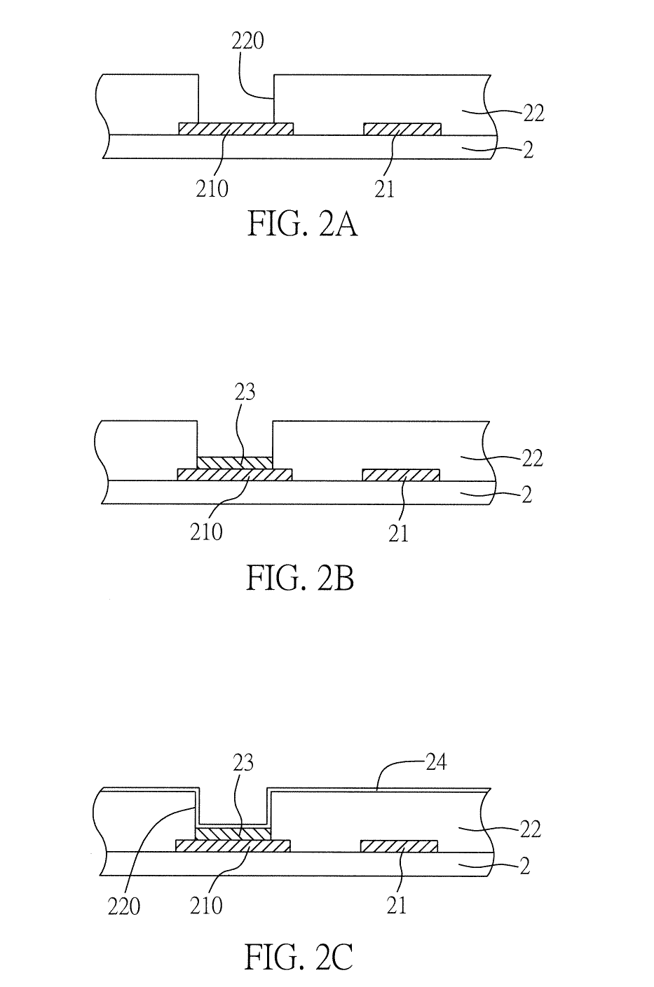

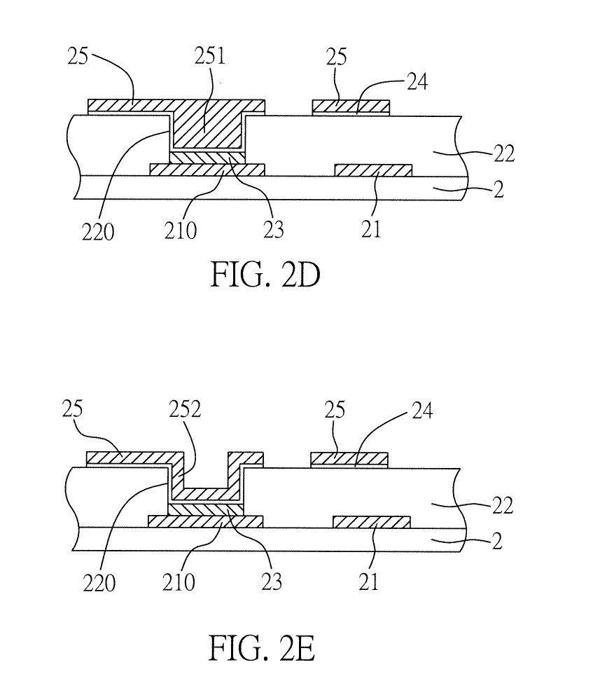

An embodiment of the method for fabricating circuit board with conductive structure of the present invention is illustrated in detail below in conjunction with FIGS. 2A to 2D.

Referring to FIG. 2A, first, a circuit board 2 is provided which has at least a circuit layer 21 with at least an electrically connecting pad 210. A dielectric layer 22 is formed on the surface of the circuit board 2 and the circuit layer, wherein a via 220 is formed at a location corresponding to the electrically connecting pad 210 of the circuit layer 21 for exposing the electrically connecting pad 210. The electrically connecting pad may electrically conduct an inner circuit (not shown) of the circuit board 2 via a conductive structure (not shown).

Referring next to FIG. 2B, a buffer metal layer 23 is formed on the electrically connecting pad 210 within the via 220 of the dielectric layer 22. In this embodiment, the buffer metal layer 23 is formed using electroless plating, such as chemical deposition or high vacuum physical deposition. The material of this buffer metal layer is characterized by high combining strength, high ductility and high conductivity, which can be formed by one of gold, silver, titanium, beryllium and alloy thereof. Preferably, the buffer metal layer 23 is formed as a gold layer covering the surface of the electrically connecting pad 210 by electroless gold plating technique. Since the material of the buffer metal layer 23 that is different from that of the electrically connecting pad has high combining strength and high ductility, the two may be strongly combined together. Meanwhile, the underlying electrically connecting pad 210 is protected by the buffer metal layer 23 during micro-etching.

Referring to FIG. 2C, a conductive layer 24 is formed on the surface of the dielectric layer 22 and the buffer metal layer. The conductive layer 24 may consist of metal, alloy or multi-layer of metals, such as one selected from the group consisting of copper, tin, nickel, chromium, titanium, copper-chromium alloy and tin-lead alloy or conductive high molecular material such as polyacetylene, polyaniline or organic sulfur polymer.

Referring to FIGS. 2D and 2D′, the conductive layer 24 is used as a current propagation path in an electroplating process that allows a conductive structure of fully-plated blind via 251 (as shown in FIG. 2D) or conductive blind via 252 (as shown in FIG. 2D′) to be formed. The conductive structure is electrically connected with the buffer metal layer 23. At the same time of forming the conductive structure, a metal layer is also formed on the surface of the dielectric layer and patterned to form another circuit layer 25. The circuit layer 25 is electrically connected to the electrically connecting pad 210 of the above circuit layer 21 through the buffer metal layer 23 and the conductive structure. The patterning process will not be further discussed as it is a well-known technique in the art.

With the fabrication method above, a circuit board with a conductive structure can be formed as shown in FIGS. 2D and 2D′, which includes a circuit board 2 formed with a circuit layer 21 with at least an electrically connecting pad 210; a dielectric layer 22 formed on the surface of the circuit board 2 with the circuit layer 21, the dielectric layer having at least a via 220 formed therein for exposing the electrically connecting pad 210; a buffer metal layer 23 formed on the surface of the electrically connecting pad 210 in the via 220 of the dielectric layer 22; and a conductive structure formed on the buffer metal layer 23. In addition, a conductive layer 24 is further formed between the buffer metal layer 23 and the conductive structure, in which the buffer metal layer is formed from a material with high ductility by electroless plating. Preferably, the buffer metal layer is a gold (Au) layer formed by electroless plating.

### Second Embodiment

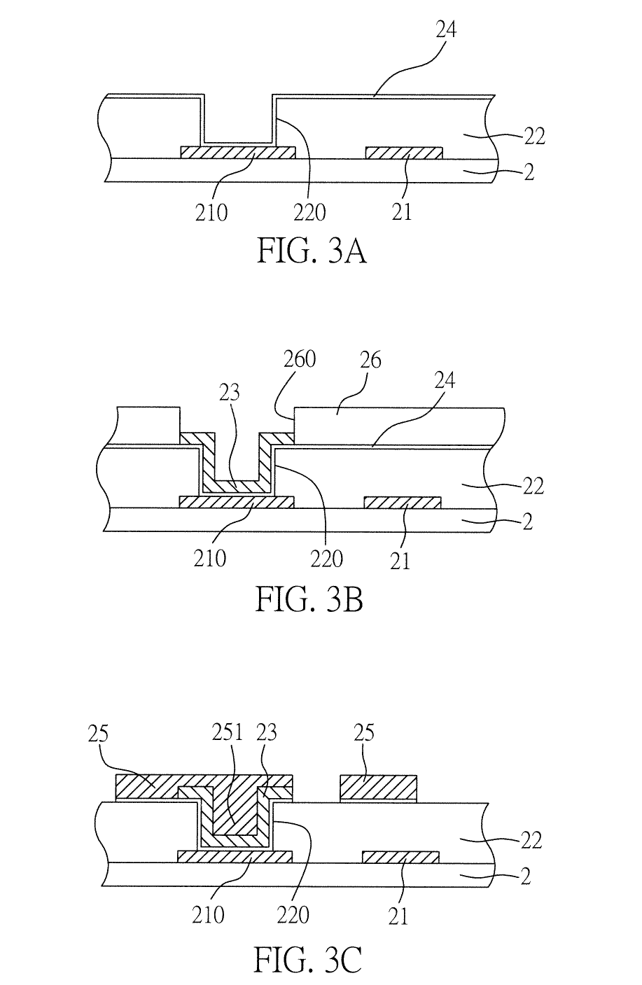

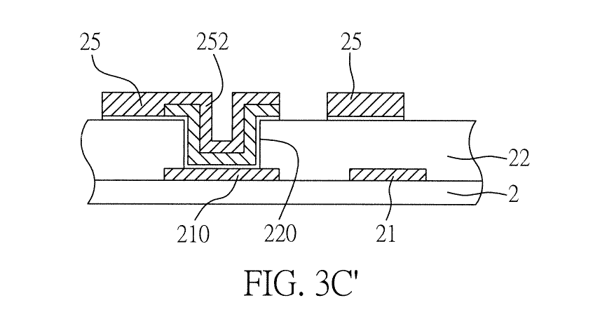

Another embodiment of the method for fabricating circuit board with conductive structure of the present invention is illustrated in conjunction with FIGS. 3A to 3C. This embodiment is different from the first embodiment in that the conductive layer is first formed in the via of the dielectric layer and the buffer metal layer and the conductive structure are formed on the surface of the conductive layer thereafter.

Referring to FIG. 3A, first, at least a circuit layer 21 is formed on the circuit board 2. The circuit layer 21 has at least an electrically connecting pad 210. A dielectric layer 22 is formed on the surface of the circuit board 2 and the circuit layer, wherein a via 220 is formed at a location corresponding to the electrically connecting pad 210 of the circuit layer 21 for exposing the electrically connecting pad 210. Then, a conductive layer 24 is formed on the surface of the dielectric layer 22 and its via 220 so that the conductive layer 24 is electrically connected to the electrically connecting pad 210.

Referring to FIG. 3B, a resist layer 26 is formed on the surface of the dielectric layer 22 and a via 260 is formed in the resist layer 26 corresponding to the via 220 of the dielectric layer 22. The aperture size of the via 260 of the resist layer is larger than that of the via 220 of the dielectric layer, thus exposing the conductive layer 24 on the surface of the dielectric layer from the via 260 of the resist layer. Thereafter, a buffer metal layer 23 is formed on the conductive layer 24 on the electrically connecting pad 210 in the via 220 of the dielectric layer and also in the via 260 of the resist layer by electroplating or electroless plating, such as chemical deposition or high vacuum physical deposition. Thus, the buffer layer 23 is formed on the electrically connecting pad 210 in the via 220 of the dielectric layer 22, on the walls of the via 220 of the dielectric layer 22 and on the surface of the dielectric layer 22 in proximity to edge of the via 220.

Referring to FIGS. 3C and 3C′, the conductive layer 24 is used as a current propagation path in an electroplating process that allows a conductive structure of fully-plated blind via 251 (as shown in FIG. 3C) or conductive blind via 252 (as shown in FIG. 3C′) to be formed and allows the conductive structure to be electrically connected to the buffer metal layer 23. At the same time of forming the conductive structure, a metal layer is also formed on the surface of the dielectric layer and patterned to form another circuit layer 25. The circuit layer 25 is electrically connected to the electrically connecting pad 210 of the above circuit layer 21 through the buffer metal layer 23 and the conductive structure. The patterning process will not be further discussed as it is a well-known technique in the art.

With the fabrication method above, a circuit board with a conductive structure can be formed as shown in FIGS. 3C and 3C′, which includes a circuit board 2 formed with a circuit layer 21 with at least an electrically connecting pad 210; a dielectric layer 22 formed on the surface of the circuit board 2 with the circuit layer 21, the dielectric layer having at least a via 220 formed therein for exposing the electrically connecting pad 210; a buffer metal layer 23 formed on the surface of the electrically connecting pad 210 in the via 220 of the dielectric layer 22, on the walls of the via 220 of the dielectric layer 22 and on the surface of the dielectric layer 22 in proximity to the edge of the via 220; and a conductive structure of fully-plated blind via 251 or conductive blind via 252 formed on the buffer metal layer 23. In addition, a conductive layer 24 is further formed between the electrically connecting pad 210 and buffer metal layer 23.

In summary, the present invention forms a buffer metal layer on the electrically connecting pad before connecting to a conductive structure. The material of the buffer metal layer is characterized by high combining strength and high ductility, allowing it to be easily combined with the electrically connecting pad or the subsequently formed conductive structure. Thus, the combining strength of the conductive structure and the electrically connecting pad is increased by the buffer metal layer. In addition, layering or fractures at the bottom of the conductive structure causing open circuit or micro open circuit can be avoided, therefore enhancing the electrical quality and stability of the circuit board. Moreover, since the buffer metal layer covers the electrically connecting pad, the electrically connecting pad is protected from damage due to over etching during a micro-etching process, thus enhancing the electroplating quality and reliability of the subsequently formed conductive structure.

The above embodiments are only used to illustrate the principles of the present invention, and they should not be construed as to limit the present invention in any way. The above embodiments can be modified by those with ordinary skills in the arts without departing from the scope of the present invention as defined in the following appended claims.

What is claimed is:

1. A method for fabricating a circuit board with a conductive structure, comprising:
providing a circuit board with a circuit layer having at least an electrically connecting pad;
forming a dielectric layer on the circuit board and the circuit layer and at least a via formed in the dielectric layer for exposing the electrically connecting pad;
forming a buffer metal layer on the electrically connecting pad in the via of the dielectric layer; and
forming a conductive structure on the buffer metal layer in the via.

2. The method of claim 1, further comprising forming a conductive layer between the buffer metal layer and the conductive structure.

3. The method of claim 2, wherein the buffer metal layer is formed by an electroless plating process.

4. The method of claim 1, further comprising forming a conductive layer between the electrically connecting pad and the buffer metal layer.

5. The method of claim 4, wherein the buffer metal layer is formed by one of an electroless plating process and an electroplating process.

6. The method of claim 5, wherein the buffer metal layer is further formed in walls of the via of the dielectric layer and on the dielectric layer in proximity to the edge of the via.

7. The method of claim 1, wherein the buffer metal layer is made of a material with high ductility.

8. The method of claim 7, wherein the buffer metal layer is a gold layer.

9. The method of claim 1, wherein, in forming the conductive structure, another circuit layer is further formed on the dielectric layer and the another circuit layer electrically connecting to the electrically connecting pad of the circuit layer through the conductive structure and the buffer metal layer.

10. The method of claim 1, wherein the conductive structure is one of a fully-plated blind via and a conductive blind via.

11. A circuit board with a conductive structure, comprising:
a circuit layer having at least an electrically connecting pad formed on the circuit board;
a dielectric layer formed on the circuit board with the circuit layer and at least a via formed in the dielectric layer for exposing the electrically connecting pad;
a buffer metal layer formed on the electrically connecting pad in the via of the dielectric layer; and
a conductive structure formed on the buffer metal layer.

12. The circuit board of claim 11, wherein a conductive layer is further formed between the buffer metal layer and the conductive structure.

13. The circuit board of claim 12, wherein the buffer metal layer is formed by an electroless plating process.

14. The circuit board of claim 11, wherein a conductive layer is further formed between the electrically connecting pad and the buffer metal layer.

15. The circuit board of claim 14, wherein the buffer metal layer is formed by one of an electroless plating process and an electroplating process.

16. The circuit board of claim 15, wherein the buffer metal layer is further formed in walls of the via of the dielectric layer and on the dielectric layer in proximity to the edge of the via.

17. The circuit board of claim 11, wherein the buffer metal layer is made of a material with high ductility.

18. The circuit board of claim 17, wherein the buffer metal layer is a gold layer.

19. The circuit board of claim 11, wherein another circuit layer is further formed on the dielectric layer and the another circuit layer electrically connecting to the electrically connecting pad of the circuit layer through the conductive structure and the buffer metal layer.

20. The circuit board of claim 11, wherein the conductive structure is one of a fully-plated blind via and a conductive blind via.
